(19) United States
(12) Patent Application Publication
(10) Pub. No.: US 2018/0190762 A1
(43) Pub. Date: Jul. 5, 2018

(54) FLEXIBLE SUBSTRATE LAMINATION BODY FOR REDUCING SURFACE STRAIN AND FLEXIBLE ELECTRONIC DEVICE COMPRISING SAME

(71) Applicant: CENTER FOR ADVANCED SOFT ELECTRONICS, Pohang-si (KR)

(72) Inventors: Kilwon CHO, Pohang-si (KR); Yoonyoung CHUNG, Seoul (KR); Hyun Ho KIM, Seoul (KR)

(21) Appl. No.: 15/740,313

(22) PCT Filed: Jul. 19, 2016
(86) PCT No.: PCT/KR2016/007828

§ 371 Date: Dec. 27, 2017

(30) Foreign Application Priority Data
Jul. 20, 2015 (KR) 10-2015-0102687

(51) Int. Cl. H01L 29/06; H01L 51/00; H01L 29/40

(52) U.S. Cl. CPC H01L 29/06; H01L 29/40; H01L 51/00

(57) ABSTRACT

Disclosed is a flexible substrate laminate including a flexible substrate and a base member configured to reduce strain of the flexible substrate on one surface of the flexible substrate. The flexible substrate laminate includes the base member for reducing surface strain to thus decrease the surface shear stress and surface strain thereof, thereby minimizing deterioration in the performance of a device. When the flexible substrate laminate is applied to various electronic devices, the electronic devices can exhibit improved bending resistance while the performance thereof is prevented from decreasing even after bending.

### TECHNICAL FIELD

The present invention relates to a flexible substrate laminate and a flexible electronic device including the same, and more particularly to a flexible substrate laminate, including a base member for reducing surface strain to thus decrease the surface shear stress and surface strain thereof, and a flexible electronic device including the same.

### BACKGROUND ART

As electronic products having improved portability in accordance with the lives of modern people have been spotlighted, many attempts have been made to reduce the size, weight and thickness of electronic products so as to increase portability. By particular virtue of technological advancements, display apparatus, mobile phones, digital instruments, information communication instruments, etc. having improved portability and mobility by forming display devices and memory devices on a flexible substrate have been developed. In recent years, the industry and market for transparent displays have been expanding, and thus flexible substrates and materials therefor have been actively developed.

Accordingly, a polymer, which is lightweight, durable and highly flexible, is mainly used for the flexible substrate. Korean Patent Application Publication No. 10-2004-0014324 discloses a transparent conductive flexible substrate configured such that a conductive thin film is formed on the surface thereof and a protective film is formed on the surface of the conductive thin film. Also, Korean Patent Application Publication No. 10-2009-0050014 discloses a transparent conductive flexible substrate, manufactured by applying a carbon nanotube composite composition on a base substrate to form a carbon nanotube composite film and acid-treating the carbon nanotube composite film in an acid solution for a predetermined period of time to form a transparent electrode on the base substrate.

However, the conventionally known flexible substrate has bending resistance that does not meet the requirements for practical use of a flexible device, and the manufacturing process thereof is complicated, thus incurring problems related to high manufacturing costs and low productivity, which is undesirable. Furthermore, shear stress is applied to the entire device, and thus surface strain caused by shear stress of the surface thereof may remarkably deteriorate the performance of the flexible device after bending of the device or upon repeated bending.

### DISCLOSURE

### Technical Problem

Accordingly, the present invention has been made keeping in mind the problems encountered in the related art, and the present invention is intended to provide a flexible substrate laminate, which includes a base member for reducing surface strain to thus decrease the surface shear stress and surface strain thereof.

In addition, the present invention is intended to provide a flexible electronic device, which includes the flexible substrate laminate, whereby deterioration in the performance thereof is minimized even after bending.

### Technical Solution

Therefore, an aspect of the present invention provides:

a flexible substrate laminate, comprising a flexible substrate and a base member configured to reduce strain of the flexible substrate on one surface of the flexible substrate.

The shear modulus G₁ of the flexible substrate may be greater than the shear modulus G₂ of the base member.

The ratio G₁/G₂ of the shear modulus G₁ of the flexible substrate and the shear modulus G₂ of the base member may satisfy Formula 1 below.

1<G₁/G₂≤10⁴ [Formula 1]

In the flexible substrate laminate subjected to bending, the surface strain γ₂ of the base member may be greater than the surface strain γ₁ of the flexible substrate.

In the flexible substrate laminate subjected to bending, the ratio γ₂/γ₁ of the surface strain γ₂ of the base member and the surface strain γ₁ of the flexible substrate may satisfy Formula 2 below.

1<γ₂/γ₁≤10³ [Formula 2]

The flexible substrate may include a polymer.

The polymer may be at least one selected from among polytetrafluoroethylene, polyimide, polyamide, polyester, polyethylene, polypropylene, polyester, polyurethane, polydimethylsiloxane, polyacrylate, polyarylate, fiber-reinforced plastic, and composite materials.

The base member may include at least one selected from among elastic polymers such as silicone, rubber, and the like.

The base member may be an adhesive.

The adhesive may include at least one selected from among silicone, polyurethane, an acrylic resin, butyl-based rubber, and polyimide.

Another aspect of the present invention provides:

a flexible electronic device, comprising a flexible substrate laminate including a flexible substrate and a base member configured to reduce strain of the flexible substrate on one surface of the flexible substrate.

The flexible substrate laminate may be adhesive tape, and the flexible electronic device may be transferred onto another substrate using the adhesive tape.

The flexible electronic device may be any one selected from among a transistor, a solar cell, an organic light-emitting diode, a tactile sensor, a radio-frequency identification tag, e-paper, and a biosensor.

The flexible electronic device may be a transistor, and

the transistor may comprise: a flexible substrate laminate including a flexible substrate and a base member configured to reduce strain of the flexible substrate on one surface of the flexible substrate; a gate electrode on the flexible substrate laminate; a gate insulating layer on the gate electrode; a source electrode and a drain electrode on the gate insulating layer; and an active layer between the source electrode and the drain electrode.

### Advantageous Effects

According to the present invention, a flexible substrate laminate includes a base member for reducing surface strain and can thus effectively decrease surface shear stress and surface strain thereof when used as a substrate, unlike conventional techniques.

In addition, when the flexible substrate laminate is applied to a flexible electronic device, the flexible electronic device can exhibit improved bending resistance while minimizing the deterioration in the performance thereof even after bending.

### DESCRIPTION OF DRAWINGS

FIG. 1 shows measurement results for evaluating bending resistance of a graphene field-effect transistor manufactured in Device Example 1;

FIG. 2 shows the results of measurement of 2D shear-lag models of the flexible substrate/base member/paper (a) and the flexible substrate (b) manufactured in Example 2 and Comparative Example 1;

FIG. 3 shows the results of measurement of surface strain depending on the bending radius in the graphene field-effect transistors manufactured in Device Example 1 and Comparative Device Example 1;

FIG. 4 schematically shows the test for changes in resistance depending on the bending of the aluminum thin film on the flexible substrate laminates of Example 2 and Comparative Example 1; and

FIG. 5 shows the results of testing of changes in resistance depending on the bending of the aluminum thin film on the flexible substrate laminates of Example 2 and Comparative Example 1.

### BEST MODE

Hereinafter, embodiments of the present invention are described in detail with reference to the appended drawings so as to be easily performed by a person having ordinary skill in the art.

However, the following description does not limit the present invention to specific embodiments, and moreover, descriptions of known techniques, even if they are pertinent to the present invention, are considered unnecessary and may be omitted insofar as they would make the characteristics of the invention unclear.

The terms herein are used to explain specific embodiments and are not intended to limit the present invention. Unless otherwise stated, the singular expression includes a plural expression. In this application, the terms “include” or “have” are used to designate the presence of features, numbers, steps, operations, elements, parts, or combinations thereof described in the specification, and should be understood as not excluding the presence or additional possible presence of one or more different features, numbers, steps, operations, elements, parts, or combinations thereof.

Further, it will be understood that when an element is referred to as being “formed” or “layered” on another element, it can be formed or layered so as to be directly attached to the entire surface or one surface of the other element, or intervening elements may be present therebetween.

Hereinafter, a detailed description will be given of a flexible substrate laminate for use in a device according to the present invention, which is set forth to illustrate but is not to be construed as limiting the present invention, and the present invention is to be defined only by the scope of the accompanying claims.

The present invention addresses a flexible substrate laminate, including a flexible substrate and a base member configured to reduce strain of the flexible substrate on one surface of the flexible substrate.

The shear modulus G₁ of the flexible substrate may be greater than the shear modulus G₂ of the base member, and the difference therebetween may satisfy Formula 1 below. The shear modulus refers to a proportional constant between shear stress and shear strain when a material undergoes shear stress in the elastic range and thus causes shear strain.

1<G₁/G₂≤10⁴ [Formula 1]

The ratio of the shear modulus of the flexible substrate and the shear modulus of the base member falls in the range of 1<G₁/G₂≤10⁴, preferably 10<G₁/G₂≤10³, and more preferably 10² G₁/G₂≤10³.

If there is no difference in shear modulus between the flexible substrate and the base member, strain of the flexible substrate cannot be reduced. On the other hand, if there is a great difference in shear modulus therebetween, it is difficult to apply the corresponding flexible substrate laminate to devices.

The base member including a low elastic material having a low shear modulus functions to absorb shear stress that is applied to the flexible substrate laminate and may thus be imparted with relatively high shear stress, and relatively low shear stress may be applied to the flexible substrate of the flexible substrate laminate. Accordingly, the surface strain may be reduced with a decrease in the shear stress of the flexible substrate.

When the base member has the same shear modulus as that of the flexible substrate, a completely uniform shear stress is applied to the flexible substrate laminate, whereby a relatively large shear stress may be applied to the flexible substrate. Thereby, surface shear strain of the flexible substrate may become large, and thus the performance of the device formed on the surface of the flexible substrate may suffer.

In the flexible substrate laminate subjected to bending, the surface strain γ₂ of the base member may be greater than the surface strain γ₁ of the flexible substrate, and the difference therebetween may satisfy Formula 2 below.

1<γ₂/γ₁≤10³ [Formula 2]

The ratio of the surface strain γ₂ of the base member and the surface strain γ₁ of the flexible substrate falls in the range of 1<γ₂/γ₁≤10³, preferably 10<γ₂/γ₁≤10³, and more preferably 10<γ₂/γ₁≤10².

If there is no difference in surface strain between the flexible substrate and the base member, deterioration in the performance of the device cannot be minimized. On the other hand, if there is too large a surface strain difference, delamination may occur between the flexible substrate and the substrate, making it difficult to realize application to devices.

The polymer may be at least one selected from among polytetrafluoroethylene, polyimide, polyamide, polyester, polyethylene, polypropylene, polyester, polyurethane, polydimethylsiloxane, polyacrylate, polyarylate, fiber-reinforced plastic, and composite materials.

The base member may include at least one selected from among elastic polymers, such as silicone, rubber, and the like.

The base member may be an adhesive.

The adhesive may include at least one selected from among silicone, polyurethane, an acrylic resin, butyl-based rubber, and polyimide.

The number of layers of the flexible substrate laminate is not necessarily limited to two, and the base member and the flexible substrate may be randomly stacked in plural numbers. Alternatively, the base member and the flexible substrate may be alternately repeatedly stacked in plural numbers.

A plurality of flexible substrates included in the flexible substrate laminate need not necessarily be composed of the same polymer, and may be composed of the same polymer, or may include some of the same polymers, or may be composed of completely different polymers.

A plurality of base members included in the flexible substrate laminate need not necessarily be composed of the same component, and may be composed of the same component, or may include some of the same components, or may be composed of completely different components.

In addition, the present invention addresses a flexible electronic device, comprising, as a substrate, a flexible substrate laminate including a flexible substrate and a base member configured to reduce strain of the flexible substrate on one surface of the flexible substrate.

The flexible substrate laminate for use in the device of the present invention may be adhesive tape, and an electronic device may be formed on the adhesive tape and then transferred onto another substrate.

Various examples of the electronic device may include a transistor, a solar cell, an organic light-emitting diode, a tactile sensor, a radio-frequency identification tag, e-paper, and a biosensor. Furthermore, any electronic device may be used so long as the flexible substrate laminate of the invention may be applied thereto.

A transistor is exemplarily described. The transistor formed on the flexible substrate laminate of the present invention may include a flexible substrate laminate including a flexible substrate and a base member configured to reduce strain of the flexible substrate on one surface of the flexible substrate, a gate electrode on the flexible substrate laminate, a gate insulating layer on the gate electrode, a source electrode and a drain electrode on the gate insulating layer, and an active layer between the source electrode and the drain electrode.

### MODE FOR INVENTION

### EXAMPLES

A better understanding of the present invention will be given through the following Examples, which are set forth to illustrate but are not to be construed to limit the scope of the present invention.

### Example 1

As a flexible substrate laminate, including a flexible substrate comprising polytetrafluoroethylene (PTFE) and an adhesive base member comprising a silicone adhesive, Scotch tape (3M™, 5480, PTFE thickness of 50 μm, silicone adhesive thickness of 44 μm) was prepared. The tape was attached onto a silicon wafer, thus obtaining a Scotch-tape-attached silicon wafer. The Scotch-tape-attached silicon wafer was spin-coated with a polyimide solution (VTEC™, PI-1388) at 3000 rpm for 30 sec, and sequentially baked at 60° C. and 150° C. for 10 min, thereby manufacturing a flexible substrate laminate configured such that a polyimide layer was formed on the PTFE flexible substrate.

### Example 2

A flexible substrate laminate was manufactured in the same manner as in Example 1, with the exception that a polyimide layer was not formed.

### Device Example 1

A flexible substrate laminate, serving as a substrate, was prepared in the same manner as in Example 1, after which a gate electrode comprising an aluminum layer (30 nm) was thermally deposited on the polyimide layer of the substrate using a shadow mask in a thermal deposition machine.

Thereafter, the aluminum layer was oxidized in an oxygen plasma chamber for 7 min under a radio-frequency (RF) power of 250 W, thus forming a gate insulating layer on the surface of the aluminum layer. During the plasma treatment, oxygen pressure was maintained at the lowest level possible in the presence of plasma. Here, the lowest possible pressure of the plasma chamber was 12 mTorr.

Next, source and drain electrodes (40 nm-thick gold on nm-thick titanium) were thermally deposited on the gate insulating layer using a shadow mask.

Finally, a graphene active layer was formed on the gate insulating layer through a dry transfer process so as to electrically connect the source and drain electrodes. Specifically, polybutadiene and PMMA were sequentially applied on graphene grown on a copper foil to form a bilayer support layer, and graphene present on the surface thereof opposite the coating surface was removed using oxygen plasma, after which the copper foil was dipped in a 0.1 M ammonium persulfate aqueous solution and thus etched. After completion of the etching of the copper foil, the PMMA/polybutadiene/graphene layer floating on the ammonium persulfate aqueous solution was moved to a distilled water bath, and the PMMA/polybutadiene/graphene layer floating on water was fixed to a perforated sample holder and dried. Next, the polybutadiene/PMMA/graphene layer fixed to the holder was brought into contact with the source and drain electrodes and the gate insulating layer, and graphene was subjected to dry transfer using heat and pressure to form a graphene active layer, thereby manufacturing a graphene field-effect transistor.

### Comparative Example 1

A polyimide film (having a thickness of 125 μm) was prepared.

### Comparative Device Example 1

A graphene field-effect transistor was manufactured in the same manner as in Device Example 1, with the exception that the polyimide film of Comparative Example 1 was used as the substrate in lieu of the flexible substrate laminate of Example 1.

### Test Examples

### Test Example 1

### Evaluation of Bending Resistance of Graphene Field-Effect Transistor

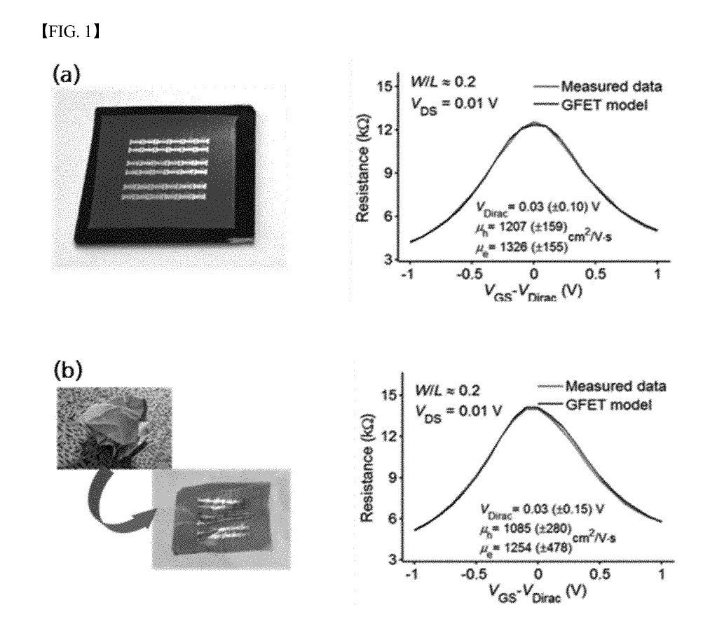

In FIG. 1, (a) shows the results of analysis of electrical properties of the graphene field-effect transistor of Device Example 1 attached onto the silicon wafer, and (b) shows the results of analysis of electrical properties of the graphene field-effect transistor of Device Example 1, which was attached onto paper, crumpled and smoothed out again.

The channel width of the graphene field-effect transistor was fixed to 85 μm, and the width-to-length ratio (W/L) was 0.2. The gate-source voltage for the channel resistance of the graphene field-effect transistors on different substrates was measured, and the electrical properties thereof were analyzed.

With reference to (a) and (b) of FIG. 1, mobility was slightly decreased after crumpling of the graphene field-effect transistor of Device Example 1, but the difference therebetween was insignificant and thus the mobility values were similar before and after crumpling, from which the electrical properties thereof can be confirmed to be efficiently maintained.

Thus, the graphene field-effect transistor of Device Example 1 exhibited superior bending resistance.

### Test Example 2

### Measurement of Shear Stress

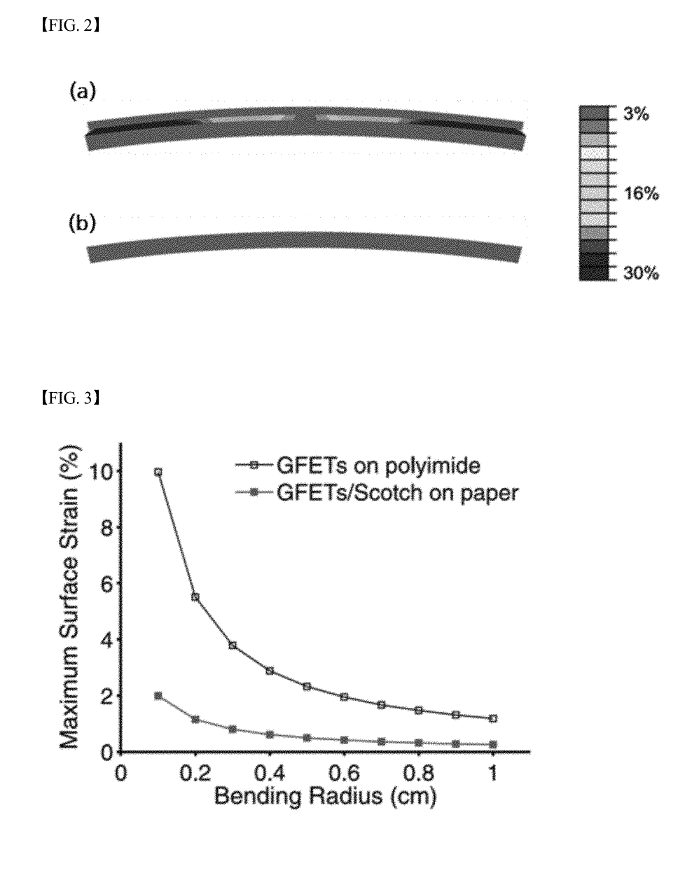

In FIG. 2, (a) shows the 2D shear-lag model after attachment of the flexible substrate laminate including the flexible substrate/base member of Example 2 to paper, and (b) shows the 2D shear-lag model of the polyimide film (flexible substrate) of Comparative Example 1.

With reference to (a) and (b) of FIG. 2, shear stress was intensively applied to the silicone adhesive portion of the Scotch tape serving as the flexible substrate laminate of Example 2, and thus the surface strain was relatively low on the surface of the flexible substrate laminate. In contrast, shear stress was uniformly applied to the entire polyimide film of Comparative Example 1, and thus surface strain was large on the surface of the polyimide film.

Thus, the flexible substrate laminate of Example 2 exhibits low surface strain compared to the polyimide film of Comparative Example 1 and thus damage to the device on the flexible substrate upon bending can be deemed to be minimized.

### Test Example 3

### Measurement of Surface Strain Depending on Bending Radius

FIG. 3 shows the results of measurement of surface strain depending on the bending radius in the graphene field-effect transistors of Device Example 1 and Comparative Device Example 1.

With reference to FIG. 3, when the bending radius was about 0.1 cm, surface strain of the graphene field-effect transistor substrate of Comparative Device Example 1 was about five times as large as the surface strain of the graphene field-effect transistor substrate of Device Example 1.

Thus, the silicone adhesive portion of the graphene field-effect transistor of Device Example 1 absorbs shear stress, whereby the surface strain of the substrate can be found to be much lower than that of the graphene field-effect transistor of Comparative Device Example 1.

### Test Example 4

### Measurement of Changes in Resistance of Metal Thin Film Depending on Number of Bending Processes

An aluminum thin film (thickness: 300 nm, length: 2 cm, width: 0.2 cm) was deposited on the flexible substrate laminate of each of Example 2 and Comparative Example 1, and bending at a bending radius of 1 mm and unbending were continuously performed, and the change in the resistance of the aluminum thin film depending on the number of bending processes was measured.

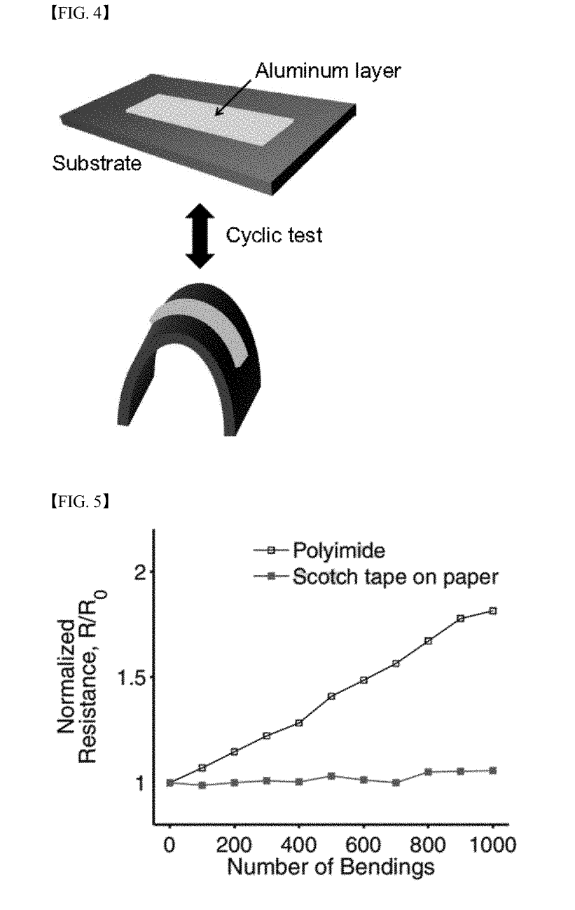

FIG. 4 schematically shows the bending test, and FIG. 5 shows the results of measurement of changes in the resistance of the aluminum thin film depending on the number of bending processes of the flexible substrate.

With reference to FIGS. 4 and 5, in the aluminum thin film on the flexible substrate laminate of Example 2, resistance was little changed despite an increase in the number of bending processes. On the other hand, in the aluminum thin film on the flexible substrate of Comparative Example 1, resistance increased in proportion to an increase in the number of bending processes. When 1000 bending processes were performed, the resistance of the aluminum thin film on the flexible substrate of Comparative Example 1 was about 1.8 times as large as that of the graphene field-effect transistor of Example 1.

Thus, even when the number of bending processes of the aluminum thin film on the Scotch tape substrate of Example 2 was increased, the deterioration in the performance of the device was insignificant, and the electrical properties thereof were efficiently maintained.

The scope of the invention is represented by the claims below rather than the aforementioned detailed description, and all of the changes or modified forms that are capable of being derived from the meaning, range, and equivalent concepts of the appended claims should be construed as being included in the scope of the present invention.

### INDUSTRIAL APPLICABILITY

According to the present invention, a flexible substrate laminate includes a base member for reducing surface strain and can thus effectively decrease surface shear stress and surface strain thereof when used as a substrate, unlike conventional techniques.

In addition, when the flexible substrate laminate is applied to a flexible electronic device, the flexible electronic device can exhibit improved bending resistance while minimizing the deterioration in the performance thereof even after bending.

1. A flexible substrate laminate, comprising:
a flexible substrate; and
a base member configured to reduce strain of the flexible substrate on one surface of the flexible substrate.

2. The flexible substrate laminate of claim 1, wherein a shear modulus (G₁) of the flexible substrate is greater than a shear modulus (G₂) of the base member.

3. The flexible substrate laminate of claim 2, wherein a ratio (G₁/G₂) of the shear modulus (G₁) of the flexible substrate and the shear modulus (G₂) of the base member satisfies Formula 1 below.
1<G₁/G₂≤10⁴ [Formula 1]

4. The flexible substrate laminate of claim 2, wherein, in the flexible substrate laminate subjected to bending, a surface strain (γ₂) of the base member is greater than a surface strain (γ₁) of the flexible substrate.

5. The flexible substrate laminate of claim 4, wherein, in the flexible substrate laminate subjected to bending, a ratio (γ₂/γ₁) of the surface strain (γ₂) of the base member and the surface strain (γ₁) of the flexible substrate satisfies Formula 2 below.
1<γ₂/γ₁≤10³ [Formula 2]

6. The flexible substrate laminate of claim 1, wherein the flexible substrate includes a polymer.

7. The flexible substrate laminate of claim 6, wherein the polymer is at least one selected from among polytetrafluoroethylene, polyimide, polyamide, polyester, polyethylene, polypropylene, polyester, polyurethane, polydimethylsiloxane, polyacrylate, polyarylate, fiber-reinforced plastic, and combinations thereof.

8. The flexible substrate laminate of claim 1, wherein the base member includes an adhesive.

9. The flexible substrate laminate of claim 8, wherein the adhesive includes at least one selected from among silicone, polyurethane, an acrylic resin, an epoxy resin, and polyimide.

10. A flexible electronic device, comprising a flexible substrate laminate including a flexible substrate and a base member configured to reduce strain of the flexible substrate on one surface of the flexible substrate.

11. The flexible electronic device of claim 10, wherein the flexible substrate laminate is an adhesive tape, and
the flexible electronic device is transferred onto another substrate using the adhesive tape and is attached thereto.

12. The flexible electronic device of claim 10, wherein the flexible electronic device is any one selected from among a transistor, a solar cell, an organic light-emitting diode, a tactile sensor, a radio-frequency identification tag, e-paper, and a biosensor.

13. The flexible electronic device of claim 12, wherein the flexible electronic device is a transistor,
the transistor comprising:
a flexible substrate laminate including a flexible substrate and a base member configured to reduce strain of the flexible substrate on one surface of the flexible substrate;
a gate electrode on the flexible substrate laminate;
a gate insulating layer on the gate electrode;
a source electrode and a drain electrode on the gate insulating layer; and
an active layer between the source electrode and the drain electrode.
